(19) United States
(12) Patent Application Publication
(10) Pub. No.: US 2010/0029053 A1
(43) Pub. Date: Feb. 4, 2010

(54) METHOD OF MANUFACTURING SEMICONDUCTOR DEVICE

(76) Inventors: Hiroshi Itokawa, Yokohama-Shi (JP); Ichiro Mizushima, Yokohama-Shi (JP); Kiyotaka Miyano, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/534,380

(22) Filed: Aug. 3, 2009

(30) Foreign Application Priority Data
Aug. 4, 2008 (JP) 2008-200742
Jun. 17, 2009 (JP) 2009-144058

(51) Int. Cl. H01L 21/336; H01L 21/322

(52) U.S. Cl. 438/306; 438/308; 257/E21.409; 257/E21.317

(57) ABSTRACT

A method of manufacturing a semiconductor device for forming an n-type FET has forming an isolation insulating film on a surface of the semiconductor substrate consisting primarily of silicon, the isolation insulating film partitioning a device region of the semiconductor substrate; forming a gate insulating film on the device region of the semiconductor substrate; forming a gate electrode on the gate insulating film; amorphizing regions to be source/drain contact regions adjacent to the gate electrode, of the device region, by ion implanting of one of a carbon cluster ion, a carbon monomer ion and a molecular ion containing carbon into the regions to be the source/drain contact regions; forming an impurity-implanted layer to be the source/drain contact regions by ion implanting at least one of arsenic and phosphorus as an n-type impurity into the amorphized regions; and activating the carbon and the impurity in the impurity-implanted layer by heat treatment.

### CROSS-REFERENCE TO RELATED APPLICATION

This application is based upon and claims the benefit of priority from the prior Japanese Patent Application No. 2008-200742, filed on Aug. 4, 2008, and No. 2009-144058, filed on Jun. 17, 2009, the entire contents of which are incorporated herein by reference.

### BACKGROUND OF THE INVENTION

1. Field of the Invention

The present invention relates to a method of manufacturing a semiconductor device for improving the operation speed of an n-type field effect transistor (FET) by applying a strain.

2. Background Art

Recently, miniaturization of semiconductor devices is proceeding, and has resulted in achievement of semiconductor devices having a gate length less than 65 nm that can operate at ultrahigh speeds.

In such FETs, which are extremely miniaturized and can operate at ultrahigh speeds, the area of a channel region beneath a gate electrode is very small compared with conventional FETs. It is known that, in the FETs concerned, the mobility of electrons or holes traveling in a channel region are therefore largely affected by a stress applied to the channel region.

There are many attempts to improve operating speeds of semiconductor devices by optimizing such a stress applied to a channel region.

As conventionally recognized, technology of silicon containing carbon (Si:C) is a promising one for manufacturing high-performance n-type FETs formed on silicon.

For example, if Si:C is embedded in a silicon substrate adjacent to a channel region of an n-type FET, a tensile stress is applied to the channel region. This increases the mobility of electrons to allow the performance of the n-type FET to be improved.

Typically, an embedded Si:C structure is formed by deeply digging a source/drain region by Reactive Ion Etching (RIE) or the like and then using vapor phase epitaxial growth, such as Remote Plasma-Enhanced Chemical Vapor Deposition (RP-CVD) or Low Pressure Chemical Vapor Deposition (LP-CVD).

In recent years, there has been reported a technique of implanting carbon monomer ions into a source/drain region by an ion implantation technique, without digging the source/drain region by RIE or the like, and then applying activation heat treatment. By the use of this technique, an embedded Si:C structure is formed (for example, see Kah Wee Ang et al., “50 nm Silicon-On-Insulator N-MOSFET Featuring Multiple Stressors: Silicon-Carbon Source/Drain Regions and Tensile Stress Silicon Nitride Liner”, 2006 Symposium on VLSI Technology Digest of Technical Papers, IEEE, 2006.).

### SUMMARY OF THE INVENTION

According to one aspect of the present invention, there is provided: a method of manufacturing a semiconductor device for forming an n-type FET, comprising:

forming an isolation insulating film on a surface of the semiconductor substrate consisting primarily of silicon, the isolation insulating film partitioning a device region of the semiconductor substrate;

forming a gate insulating film on the device region of the semiconductor substrate;

forming a gate electrode on the gate insulating film;

amorphizing regions to be source/drain contact regions adjacent to the gate electrode, of the device region, by first ion implanting one of a carbon cluster ion, a carbon monomer ion and a molecular ion containing carbon into the regions to be the source/drain contact regions;

forming an impurity-implanted layer to be the source/drain contact regions by second ion implanting at least one of arsenic and phosphorus as an n-type impurity into the amorphized regions; and

activating the carbon and the impurity in the impurity-implanted layer by heat treatment.

According to another aspect of the present invention, there is provided: a method of manufacturing a semiconductor device for forming an n-type FET, comprising:

forming an isolation insulating film on a surface of the semiconductor substrate consisting primarily of silicon, the isolation insulating film partitioning a device region of the semiconductor substrate;

forming a gate insulating film on the device region of the semiconductor substrate;

forming a gate electrode on the gate insulating film;

amorphizing regions to be source/drain contact regions adjacent to the gate electrode, of the device region, by first ion implanting at least one of arsenic and phosphorus as an n-type impurity into the regions to be the source/drain contact regions;

forming an impurity-implanted layer to be the source/drain contact regions by second ion implanting one of a carbon cluster ion, a carbon monomer ion and a molecular ion containing carbon into the amorphized regions; and

activating the carbon and the impurity in the impurity-implanted layer by heat treatment.

### BRIEF DESCRIPTION OF THE DRAWINGS

FIG. 1 is a figure showing a cross section of processes of a method of manufacturing a semiconductor device according to a first embodiment which is an aspect of the present invention;

FIG. 2 is a figure showing a cross section of process of a method of manufacturing the semiconductor device according to the first embodiment, is continuous from FIG. 1;

FIG. 3 is a figure showing a cross section of process of the method of manufacturing the semiconductor device according to the first embodiment, is continuous from FIG. 2;

FIG. 4 is a figure showing a cross section of process of the method of manufacturing the semiconductor device according to the first embodiment, is continuous from FIG. 3;

FIG. 5 is a figure showing a cross section of process of the method of manufacturing the semiconductor device according to the first embodiment, is continuous from FIG. 4;

FIG. 6 is a figure showing a cross section of process of the method of manufacturing the semiconductor device according to the first embodiment, is continuous from FIG. 5;

FIG. 7 is a figure showing a cross section of process of the method of manufacturing the semiconductor device according to the first embodiment, is continuous from FIG. 6;

FIG. 8 is a figure showing a cross section of process of the method of manufacturing the semiconductor device according to the first embodiment, is continuous from FIG. 7;

FIG. 9 is a figure showing relationships between a carbon concentration at a substitutional site of the silicon (100) substrate to which carbon cluster ions (C₇H₇) are implanted and the activation heat treatment conditions;

FIG. 10 is showing relationships between a treatment time of soak annealing and a carbon concentration at a substitutional site;

FIG. 11 is a figure showing a relationship between a depth of a silicon (100) substrate into which carbon cluster ions (C₇H₇) are implanted and a carbon concentration after heat treatment;

FIG. 12 is a figure showing the dependency of solid phase growth velocities on impurity concentrations of a (100) single-crystal silicon substrate in a nitrogen atmosphere at 500° C.;

FIG. 13 is a figure showing a cross section of process of a method of manufacturing a semiconductor device according to a second embodiment which is another aspect of the present invention;

FIG. 14 is a figure showing a cross section of process of the method of manufacturing a semiconductor device according to the second embodiment, is continuous from FIG. 13;

FIG. 15 is a figure showing a conventional model in a vicinity of a crystal/amorphous interface of a silicon substrate after heat treatment for activation and a relationship of a carbon concentration with respect to a depth of the substrate; and

FIG. 16 is s figure showing a model of a third embodiment in the vicinity of a crystal/amorphous interface of a silicon substrate after heat treatment for activation and a relationship of a carbon concentration with respect to a depth of the substrate.

### DETAILED DESCRIPTION

When carbon monomer ions are implanted by an ion implantation technique in a way as described above to form an embedded Si:C structure, the solubility limit of carbon in Si is extremely low, 3.5×10¹⁷ cm⁻³ (at the melting point). It is therefore difficult to dissolve carbon at substitutional sites in Si at a high concentration for straining Si crystal without precipitation of SiC.

Further, the carbon concentration at substitutional sites in Si is low, ranging from about 1.0 to 1.5%. Accordingly, the carbon concentration at interstitial sites is high.

Because crystalline recovery in a carbon-ion-implanted region is incomplete, degradation in transistor characteristics, such as a junction leakage error, occurs.

For the purpose of crystalline recovery of an amorphous Si layer after implanting of carbon ions, implanting of carbon cluster ions that reduces the dose rate to be able to suppress self-annealing is considered to be more effective than implanting of monomer ions.

However, there is no carbon activation method that realizes complete crystalline recovery while achieving a high carbon concentration at substitutional sites. That is, conventional technologies as described above cannot improve the operational performance of n-type FETs.

In embodiments according to the present invention, there is proposed a method of manufacturing a semiconductor device to form an n-type FET with an improved operation speed.

Each embodiment according to the present invention will be described below with reference to the accompanying drawings.

### First Embodiment

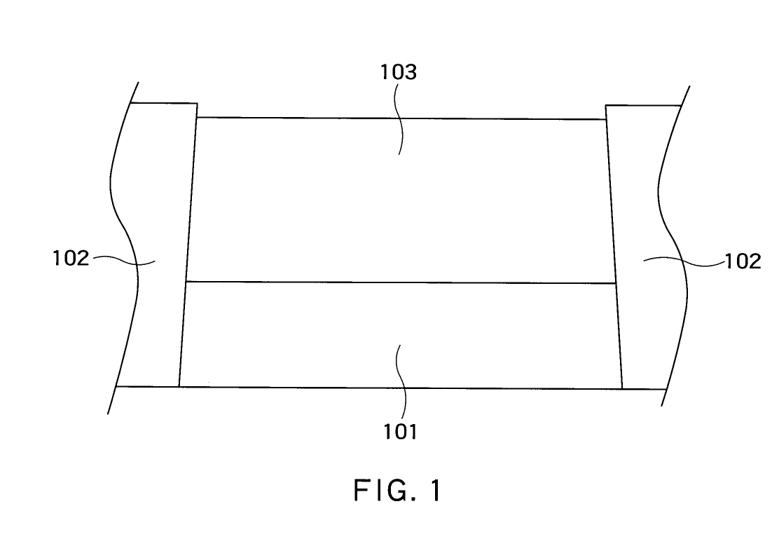

FIGS. 1 to 8 show cross sections of processes of a method of manufacturing a semiconductor device according to a first embodiment, which is an aspect of the present invention.

First, an isolation insulating film 102 to partition a device region of a silicon substrate 101 is formed on the surface of the semiconductor substrate (silicon substrate) 101 consisting primarily of silicon. The isolation insulating film 102 is made, for example, of a silicon oxide film. Further, by ion implantation, a p-type well diffusion layer region 103 is formed in the device region surrounded with the isolation insulating film 102 (FIG. 1).

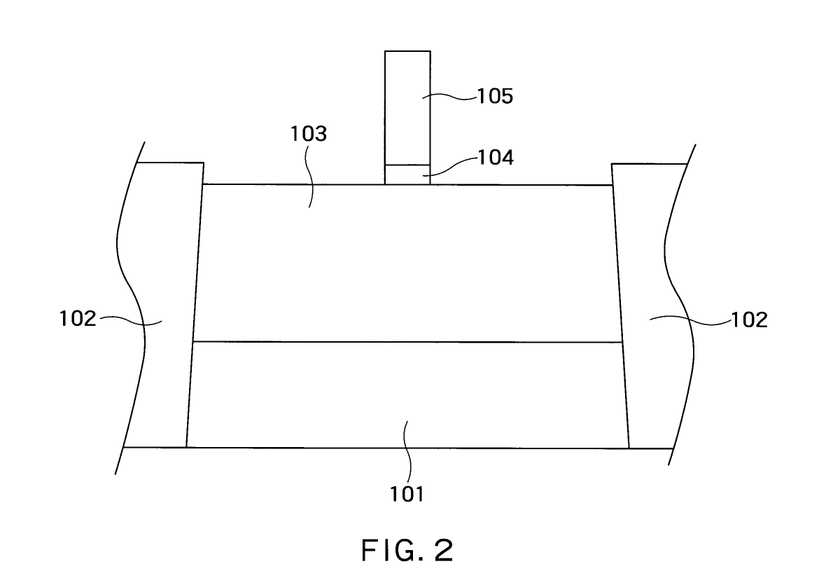

Next, a gate insulating film 104 is formed on the device region (the well diffusion layer region 103) of the silicon substrate 101. Further, a polysilicon 105, which will be a gate electrode, and a silicon nitride film (not shown), which is a mask material, are sequentially formed on the gate insulating film 104. By patterning this laminated structure film, a gate electrode structure is formed (FIG. 2).

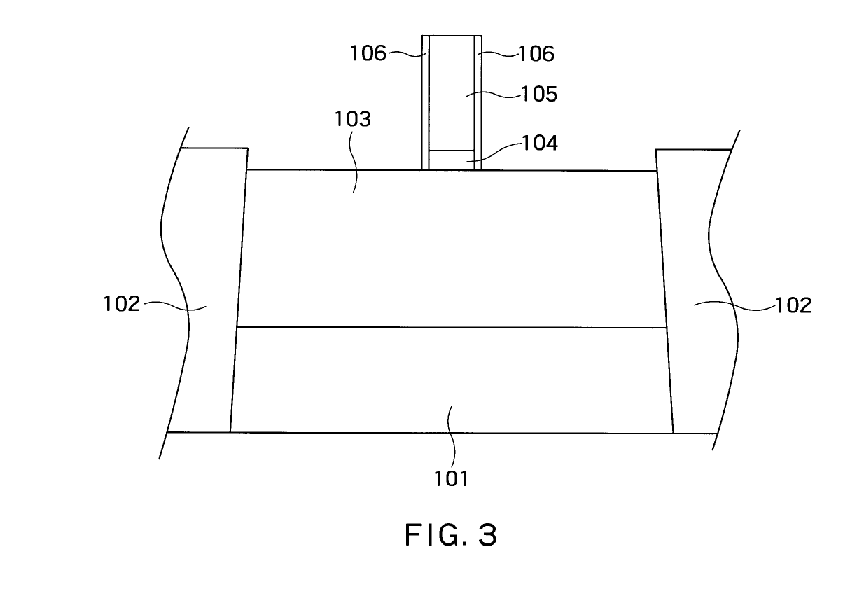

Next, a thin silicon nitride film (e.g., from about 2 to 10 nm) is deposited, and the silicon nitride film is anisotropically etched by RIE or the like. Thus, a silicon nitride film sidewall (offset spacer) 106 is formed on the surface of a side wall of the gate electrode (FIG. 3).

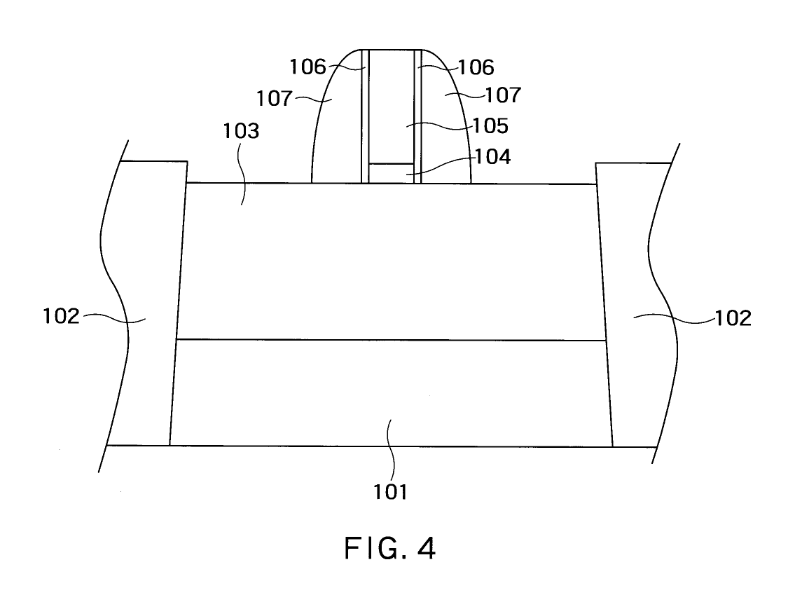

Next, a thin silicon oxide film (e.g., from about 5 to 20 nm) is deposited, and the silicon oxide film is anisotropically etched by RIE or the like. Thus, a silicon oxide film sidewall 107 is formed on the surface of the side wall of the gate electrode 105 with the silicon nitride film sidewall 106 interposed therebetween (FIG. 4).

Next, carbon cluster ions are implanted into the exposed p-type well diffusion layer region 103 by an ion implantation technique under a condition that the peak concentration of carbon is 2% or more. That is, regions to be source/drain contact regions sandwiching (adjacent to) the gate electrode 105, of the device region, are amorphized by implanting carbon cluster ions into the regions to be source/drain contact regions. Note that the carbon cluster ions are at least one of C₇H₇ and C₅H₅.

Further, at least one of arsenic and phosphorus as an n-type impurity is implanted at a dose of 1×10¹⁵ cm⁻² or more into the amorphized regions by an ion implantation technique.

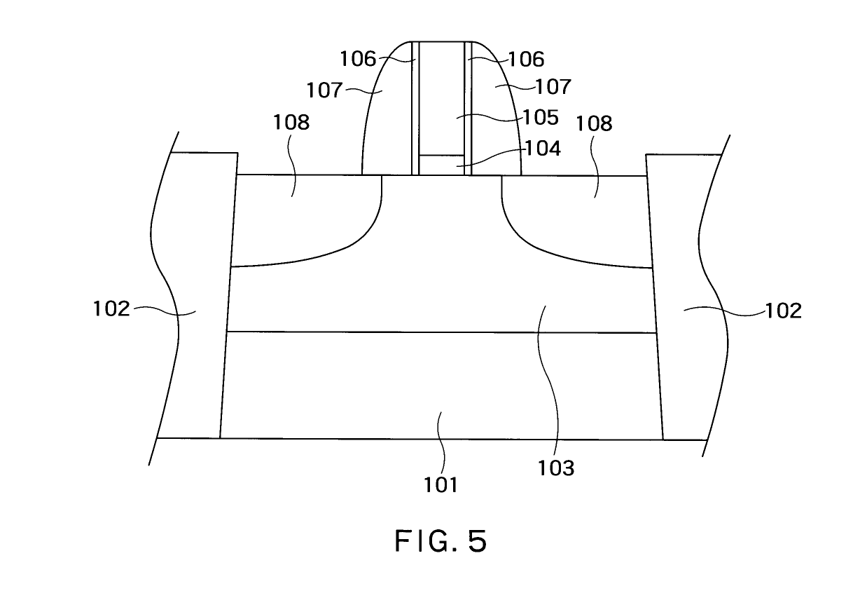

Thus, an impurity-implanted layer 108 to be n-type source/drain contact regions is formed above the exposed surface of the silicon substrate 101 (or the exposed surface of the well diffusion layer region 103) (FIG. 5).

Note that, in order to obtain a carbon concentration of about 2% at substitutional sites, the peak concentration of carbon needs to be 2% or more as described above.

In the impurity-implanted layer 108, the n-type impurity (arsenic, phosphorus) is ion implanted so that the concentration of the impurity is maximum near a depth at which the carbon concentration is maximum. This compensates for a decrease of a solid phase growth velocity, which is caused by carbon, allowing a desired crystallinity to be obtained as described later.

Next, after the silicon oxide film sidewall 107 is removed, a silicon oxide film is deposited and anisotropic etching, such as RIE, is performed. Thus, a silicon oxide sidewall 109 is formed. Thereafter, impurities, such as arsenic and phosphorus, are implanted by an ion implantation technique.

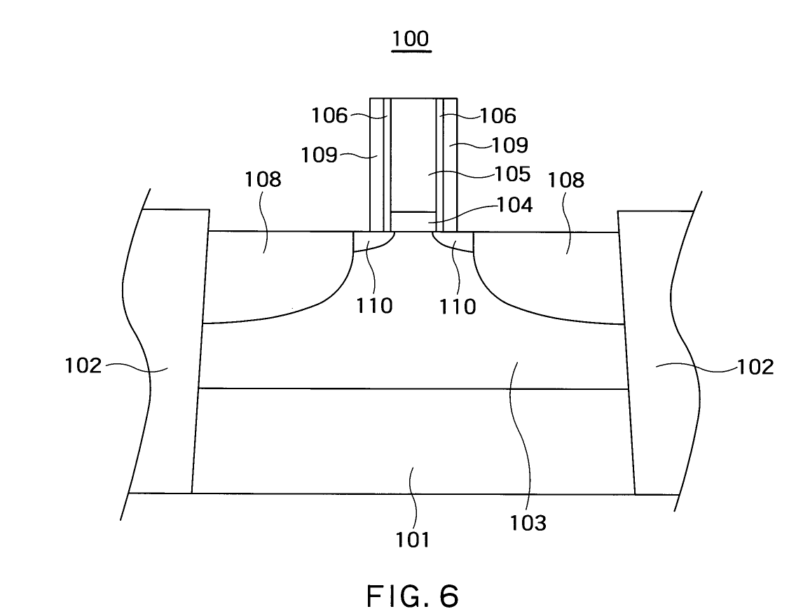

Thus, an impurity-implanted layer 110 to be n-type source/drain extension regions is formed on the surface of the n-type well diffusion layer region 103 (FIG. 6).

Next, heat treatment is performed at high temperature for an extremely short time by means of Xe flash lamp annealing. By the Xe flash lamp annealing, the substrate surface temperature of the silicon substrate 101 is controlled to be in a range from 1200 to 1400° C. The treatment time ranges from 0.2 to 2.0 ms.

This annealing activates the carbon and the impurity in the impurity-implanted layer 108 to be n-type source/drain contact regions, and activates the carbon and the impurity in the impurity-implanted layer 110 to be n-type source/drain extension regions.

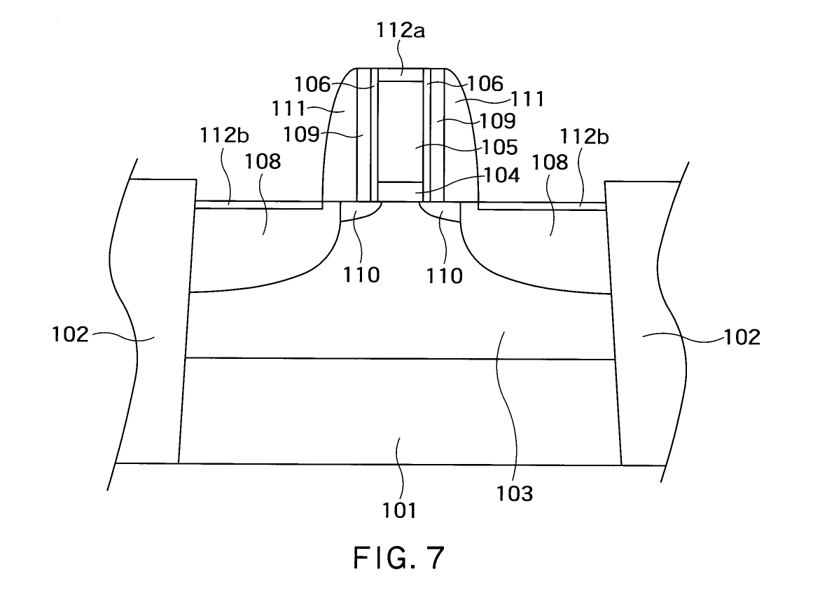

Next, a silicon nitride film is deposited, and the silicon nitride film is anisotropically etched by RIE or the like. Thus, a silicon nitride film sidewall 111 is formed. Thereafter, nickel monosilicide (NiSi) films 112a and 112b are formed on the surface of the source/drain contact region (impurity-implanted layer) 108 and the surface of the polycrystal gate electrode 105 by a silicidation technique (FIG. 7).

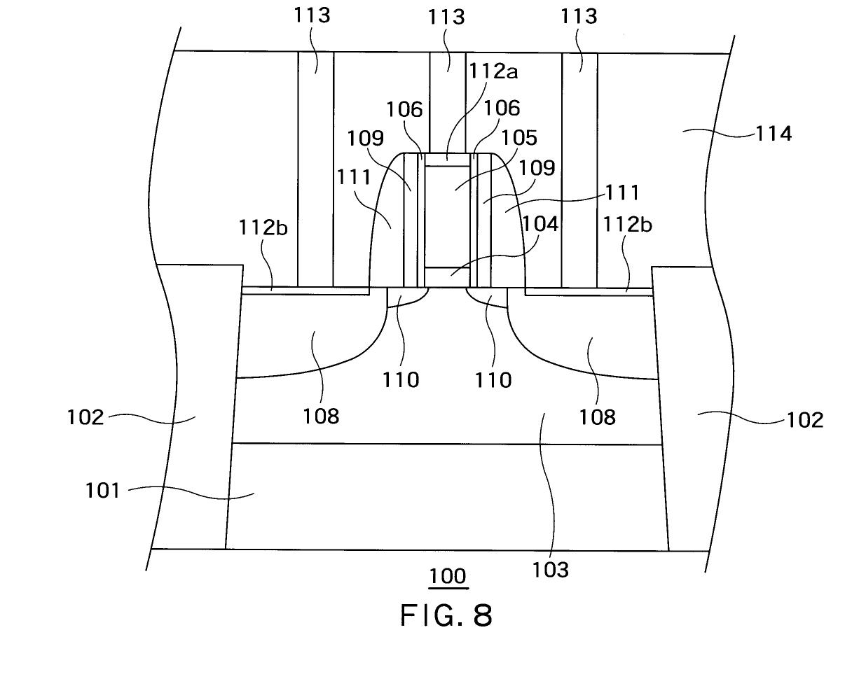

Next, an interlayer insulating film 114 is formed above the silicon substrate 101. Further, a wiring layer connected to the nickel monosilicide (NiSi) films 112a and 112b is formed in the interlayer insulating film 114. Thus, a semiconductor device 100 functioning as a transistor device is completed (FIG. 8).

As such, carbon with a high concentration is implanted into the source/drain contact region 108 by a carbon cluster ion implantation technique to amorphize it. This allows self-annealing upon the ion implantation to be suppressed. Excellent crystalline recovery can thus be achieved by later heat treatment.

Further, arsenic and phosphorus are implanted at least one of before and after implanting carbon cluster ions by an ion implantation technique. This can compensate for the decreased velocity of silicon recrystallization (solid phase growth) by carbon as described later.

Further, activation of the carbon and the arsenic and phosphorus is performed by heat treatment at high temperature for an extremely short time. Thus, a strained carbon-containing silicon crystal whose crystal structure has extremely excellent crystallinity as same as that of silicon and that has a high carbon concentration at substitutional sites can be formed in the source/drain contact region.

As a result, a tensile stress is applied to a channel region of an n-type FET, enabling the mobility of carriers (electrons) flowing through a channel area to be increased. That is, an n-type FET with high performance can be obtained.

As described above, in the present embodiment, the impurity-implanted layer 108 to be an n-type source/drain contact region and the impurity-implanted layer 110 to be an n-type source/drain extension region are activated. This activation is achieved by heat treatment at high temperature for an extremely short time by means of Xe flash lamp annealing. By the Xe flash lamp annealing, the silicon substrate surface temperature is controlled to be in a range from 1200 to 1400° C., and the heat treatment time is in a range from 0.2 to 2.0 ms.

However, similar heat treatment at high temperature for an extremely short time may be performed by means of laser annealing using a semiconductor laser, a carbon dioxide gas laser or the like, instead of the Xe flash lamp annealing.

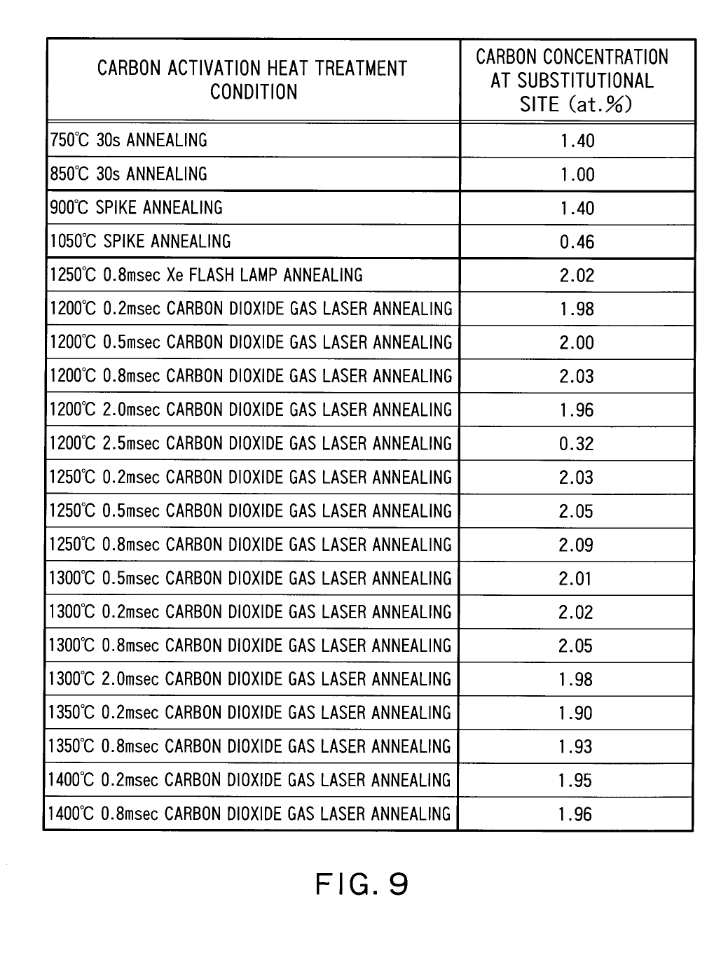

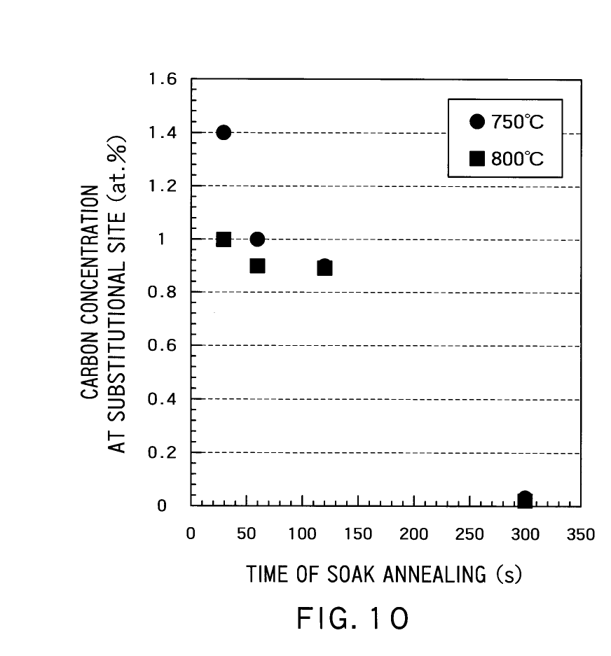

Here, FIG. 9 shows relationships between the carbon concentration at the substitutional site of the silicon (100) substrate to which carbon cluster ions (C₇H₇) are implanted and the activation heat treatment conditions. FIG. 10 shows relationships between the treatment time of soak annealing and the carbon concentration at the substitutional site.

Note that in FIG. 9, concentration distributions in the substrate that are obtained by implanting carbon cluster ions (C₇H₇) are 3×10¹⁵ cm⁻² at an acceleration energy of 9 keV, 3×10¹⁵ cm⁻² at an acceleration energy of 6 keV, and 1.5×10¹⁵ cm⁻² at an acceleration energy of 3 keV. The distributions are equivalent to concentration distributions obtained with conditions for implanting carbon monomer ions. Also, the carbon concentrations at the substitutional site in FIGS. 9 and 10 are ones measured in the vicinity of 30 nm from the surface of the substrate.

As shown in FIG. 9, in activation of carbon by soak annealing at 750° C. and 850° C. and by spike annealing at 900° C. and 1050° C., the carbon concentrations at the substitutional site are low, ranging from 0.46% to 1.4%. That is, the carbon concentration at the interstitial site is high.

As shown in FIG. 10, in the soak annealing mentioned above, the carbon concentration at the substitutional site decreases as the treatment time increases.

In the case of activation heat treatment close to thermal equilibrium, like such soak annealing and spike annealing at 900° C. and 1050° C., the solubility limit of carbon in Si is extremely low (3.5×10 cm⁻² at the melting point). It is therefore difficult to achieve a high carbon concentration at the substitutional site.

On the other hand, as shown in FIG. 9, in activation by heat treatment by means of Xe flash lamp annealing and laser annealing (silicon substrate surface temperature in a range from 1200 to 1400° C., treatment time in a range from 0.2 to 2.0 ms), a carbon concentration of about 2.0% at the substitutional site can be achieved.

As such, heat treatment at high temperature for an extremely short time, which is thermal nonequilibrium obtained by the Xe flash lamp annealing and laser annealing described above, can achieve a high carbon concentration at the substitutional site.

Note that the relationships between carbon concentrations at the substitutional site and activation heat treatment conditions in the case of selecting C₅H₅ as carbon cluster ions are the same as those shown in FIG. 9.

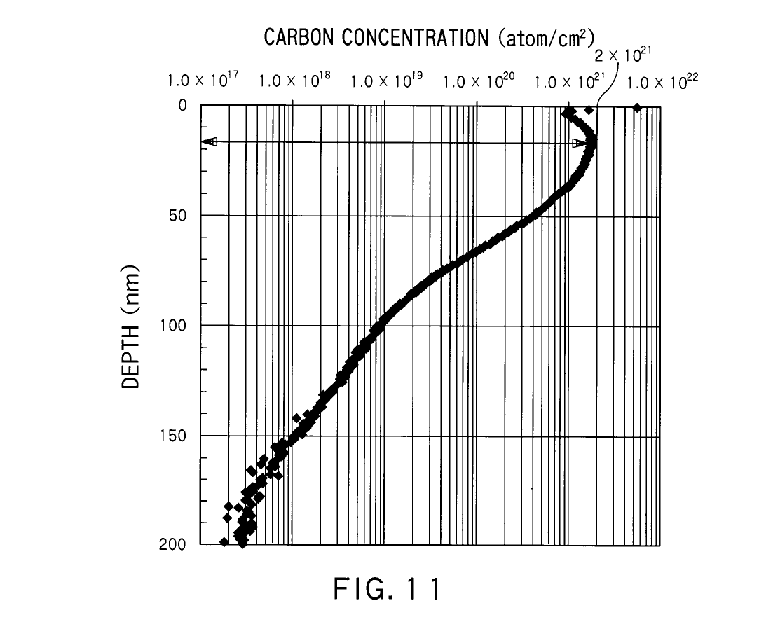

Here, FIG. 11 shows the relationship between a depth of a silicon (100) substrate into which carbon cluster ions (C₇H₇) are implanted and a carbon concentration after heat treatment.

Note that, in FIG. 11, the silicon (100) substrate is subjected to heat treatment by controlling the surface temperature of the silicon (100) substrate to be 1250° C. for 0.8 ms by means of Xe flash lamp annealing.

As shown in FIG. 11, the Si (100) substrate into which carbon cluster ions are implanted is subjected to heat treatment by Xe flash lamp annealing, so that the carbon concentration is at a peak value (2×10²¹ cm⁻³) near a depth in a range from 20 to 30 nm. The area in which the carbon concentration reaches the peak value is one in which silicon solid phase growth stops. In the area, many crystal defects, such as stacking faults and twins, are formed. Note that similar results are obtained by laser annealing at a substrate surface temperature of 1350° C. for treatment time of 0.8 ms.

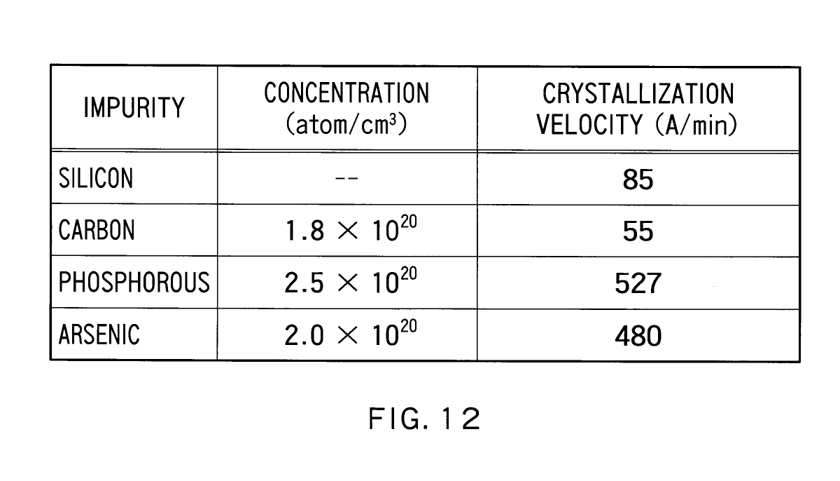

Here, FIG. 12 shows the dependency of solid phase growth velocities on impurity concentrations of a (100) single-crystal silicon substrate in a nitrogen atmosphere at 500° C.

As shown in FIG. 12, carbon decreases the solid phase growth velocity of the (100) single-crystal silicon. This results in a phenomena in which solid phase growth stops to generate defects.

On the other hand, arsenic or phosphorus that can be used as an n-type dopant increases the solid phase growth velocity of the (100) single-crystal silicon.

Arsenic or phosphorus that can be used as an n-type dopant is ion implanted into a region into which carbon cluster ions have been implanted. Further, carbon is activated by heat treatment at high temperature for an extremely short time, which is extremely thermal non-equilibrium and is achieved by Xe flash lamp annealing or laser annealing. This allows crystalline recovery to be performed while achieving a high carbon concentration at substitutional sites.

As described above, with a method of manufacturing a semiconductor device according to the present embodiment, an n-type FET with an improved operation speed can be formed.

Note that in a process shown in FIG. 5, after ion implanting of an impurity (arsenic, phosphorus), carbon and the impurity in the impurity-implanted layer 108 are activated by RTA (e.g., from 750 to 850° C., from 30 to 120 s). This improves crystallinity of the impurity-implanted layer 108. Thereafter, carbon and the impurity in the impurity-implanted layer 108 may further be activated by heat treatment, such as the Xe flash lamp annealing mentioned before.

This can further improve crystallinity of the source/drain contact regions (the impurity-implanted layer 108).

In the present embodiment, in a process shown in FIG. 5, after carbon cluster ions are ion implanted, at least one of arsenic and phosphorus is ion implanted as an n-type impurity, thereby forming the impurity-implanted layer 108.

In the process shown in FIG. 5, however, the regions to be source/drain contact regions sandwiching (adjacent to) the gate electrode 105, of the device region, are amorphized by ion implanting at least one of arsenic and phosphorus as an n-type impurity into the regions to be source/drain contact regions. Further, the impurity-implanted layer 108 to be source/drain contact regions may be formed by implanting carbon cluster ions into the amorphized region. In this case, the same action and effects as those in the present embodiment can be obtained.

In this case, after carbon cluster ions are implanted, carbon and the impurity in the impurity-implanted layer 108 are activated by RTA (e.g., from 750 to 850° C., from 30 to 120 s). This improves crystallinity of the impurity-implanted layer 108. Thereafter, carbon and the impurity in the impurity-implanted layer 108 may further be activated by heat treatment, such as the Xe flash lamp annealing mentioned before.

Also, in this case, crystallinity of the source/drain contact regions (the impurity-implanted layer 108) can further be improved.

### Second Embodiment

In the first embodiment, an example where after source/drain contact regions are formed, source/drain extension regions are formed has been described. The order of forming these regions may be reversed.

In a present second embodiment, an example of forming source/drain contact regions after forming source/drain extension regions will be described.

Note that in a method of manufacturing a semiconductor device according to the second embodiment, the processes shown in FIGS. 1 to 3 of the first embodiment are the same.

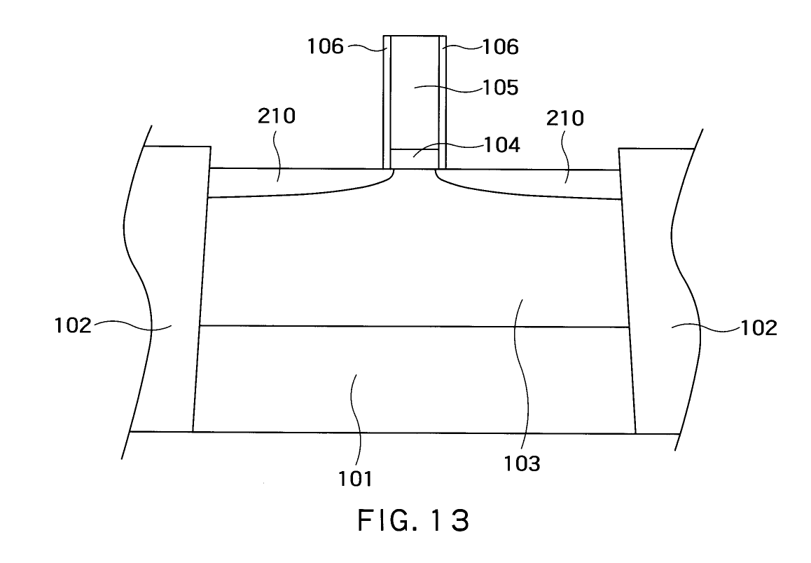

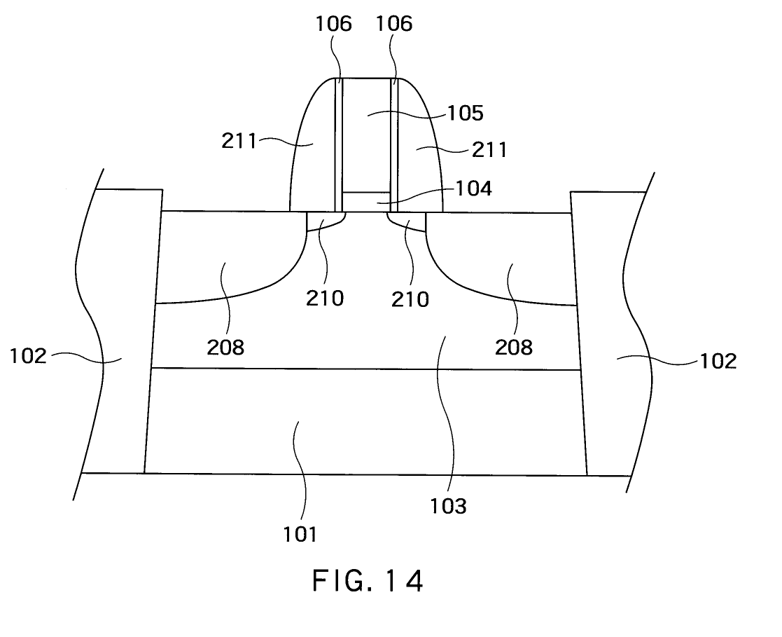

FIGS. 13 and 14 show cross sections of processes of the method of manufacturing a semiconductor device according to the second embodiment, which is another aspect of the present invention.

First, like the first embodiment, the silicon nitride film sidewall (offset spacer) 106 is formed on the surface of a side wall of the gate electrode.

Next, impurities such as arsenic and phosphorus are ion implanted into the exposed p-type well diffusion layer region 103 by an ion implantation technique.

Thus, an impurity-implanted layer 210 to be n-type source/drain extension regions is formed on the surface of the n-type well diffusion layer region 103 (FIG. 13).

Next, a silicon nitride film is deposited, and the silicon nitride film is anisotropically etched by RIE or the like. Thus, a silicon nitride film sidewall 211 is formed on the surface of the side wall of the gate electrode 105 with the silicon nitride film sidewall 106 interposed therebetween.

Then, carbon cluster ions are implanted into the exposed p-type well diffusion layer region 103 by an ion implantation technique under a condition that the peak concentration of carbon is 2% or more. That is, regions to be source/drain contact regions sandwiching (adjacent to) the gate electrode 105, of the device region, are amorphized by implanting carbon cluster ions into the regions to be source/drain contact regions. Note that the carbon cluster ions are at least one of C₇H₇ and C₅H₅.

Further, at least one of arsenic and phosphorus as an n-type impurity is implanted into the amorphized regions at a dose of 1×10¹⁵ cm⁻² or more by an ion implantation technique.

Thus, an impurity-implanted layer 208 to be n-type source/drain contact regions is formed on an exposed surface of the silicon substrate 101 (FIG. 14).

Next, heat treatment is performed at high temperature for an extremely short time by means of Xe flash lamp annealing. By the Xe flash lamp annealing, the substrate surface temperature of the silicon substrate 101 is controlled to be in a range from 1200 to 1400° C. The treatment time is in a range from 0.2 to 2.0 ms.

This annealing activates the carbon and the impurity in the impurity-implanted layer 208 to be n-type source/drain contact regions, and activates the carbon and the impurity in the impurity-implanted layer 210 to be n-type source/drain extension regions.

Subsequently, in the same way as shown in FIGS. 7 and 8 of the first embodiment, a semiconductor device, which is a transistor device, is completed.

As such, carbon with a high concentration is implanted into the source/drain contact regions 208 by a carbon cluster ion implantation technique to amorphize the regions. This allows self-annealing upon the ion implantation to be suppressed. Excellent crystalline recovery can thus be achieved by later heat treatment.

Further, like the first embodiment, arsenic and phosphorus are implanted at least one of before and after implanting carbon cluster ions by an ion implantation technique. This can compensate for the decreased velocity of recrystallization (solid phase growth) of silicon, which is caused by carbon, as described later.

Further, like the first embodiment, activation of the carbon and the arsenic and phosphorus is performed at high temperature for an extremely short time. Thus, a strained carbon-containing silicon crystal whose crystal structure has extremely excellent crystallinity as same as that of silicon and that has a high carbon concentration at the substitutional site can be formed in the source/drain contact region.

As a result, a tensile stress is applied to a channel region of an n-type FET, enabling the mobility of carriers (electrons) flowing through a channel area to be increased. That is, an n-type FET with high performance can be obtained.

As described above, in the present embodiment, the impurity-implanted layer 208 to be n-type source/drain contact regions and the impurity-implanted layer 210 to be n-type source/drain extension regions are activated. This activation is achieved by heat treatment at high temperature for an extremely short time by means of Xe flash lamp annealing. By the Xe flash lamp annealing, the silicon substrate surface temperature is controlled to be in a range from 1200 to 1400° C., and the heat treatment time ranges from 0.2 to 2.0 ms.

However, similar heat treatment at high temperature for an extremely short time may be performed by means of laser annealing using a semiconductor laser, a carbon dioxide gas laser or the like, instead of the Xe flash lamp annealing.

As described above, with a method of manufacturing a semiconductor device according to the present embodiment, an n-type FET with an improved operation speed can be formed.

Note that in a process shown in FIG. 14, after ion implanting of an impurity (arsenic, phosphorus), carbon and the impurity in the impurity-implanted layer 108 are activated by RTA (e.g., from 750 to 850° C., from 30 to 120 s). This improves crystallinity of the impurity-implanted layer 208. Thereafter, the carbon and the impurity in the impurity-implanted layer 208 may further be activated by heat treatment, such as the Xe flash lamp annealing mentioned before.

This can further improve crystallinity of the source/drain contact regions (the impurity-implanted layer 208).

In the present embodiment, in a process shown in FIG. 14, after carbon cluster ions are ion implanted, at least one of arsenic and phosphorus is ion implanted as an n-type impurity, thereby forming the impurity-implanted layer 208.

In the process shown in FIG. 14, however, regions to be source/drain contact regions sandwiching (adjacent to) the gate electrode 105, of the device region, are amorphized by ion implanting at least one of arsenic and phosphorus as an n-type impurity into the regions to be source/drain contact regions. Further, the impurity-implanted layer 208 to be the source/drain contact regions may be formed by implanting carbon cluster ions into the amorphized regions. In this case, the same action and effects as those in the present embodiment can be obtained.

In this case, after carbon cluster ions are implanted, carbon and the impurity in the impurity-implanted layer 208 are activated by RTA (e.g., from 750 to 850° C., from 30 to 120 s). This improves crystallinity of the impurity-implanted layer 208. Thereafter, carbon and the impurity in the impurity-implanted layer 208 may further be activated by heat treatment, such as the Xe flash lamp annealing mentioned before.

Also, in this case, crystallinity of the source/drain contact regions (the impurity-implanted layer 208) can further be improved.

Note that in the above first and second embodiments, description has been given on the case where carbon cluster ions are implanted into regions to be an impurity-implanted layer, so that carbon to be substituted at substitutional sites of a silicon crystal is supplied to the regions to be the impurity-implanted layer.

However, carbon monomer ions and molecular ions containing carbon may be implanted into regions to be an impurity-implanted layer. This holds true for the following embodiment.

### Third Embodiment

As described above with reference to FIG. 11, in the impurity-implanted layer, an area where the carbon concentration reaches a peak value is one where silicon solid phase growth stops. In the area, many crystal defects, such as stacking faults and twins, are formed.

That is, if the concentration of carbon supplied to the impurity-implanted layer is higher than the concentration of carbon to be substituted at substitutional sites of a silicon crystal by heat treatment for activation, surplus carbon that is not substituted by activation precipitates in the amorphous region. This results in crystal defects as described above.

In a third embodiment, description will be given on a case of setting a condition on the carbon concentration in ion implantation so as to suppress crystal defects as described above. Note that conditions other than that on the carbon concentration in ion implantation are the same as those in the first and second embodiments described above.

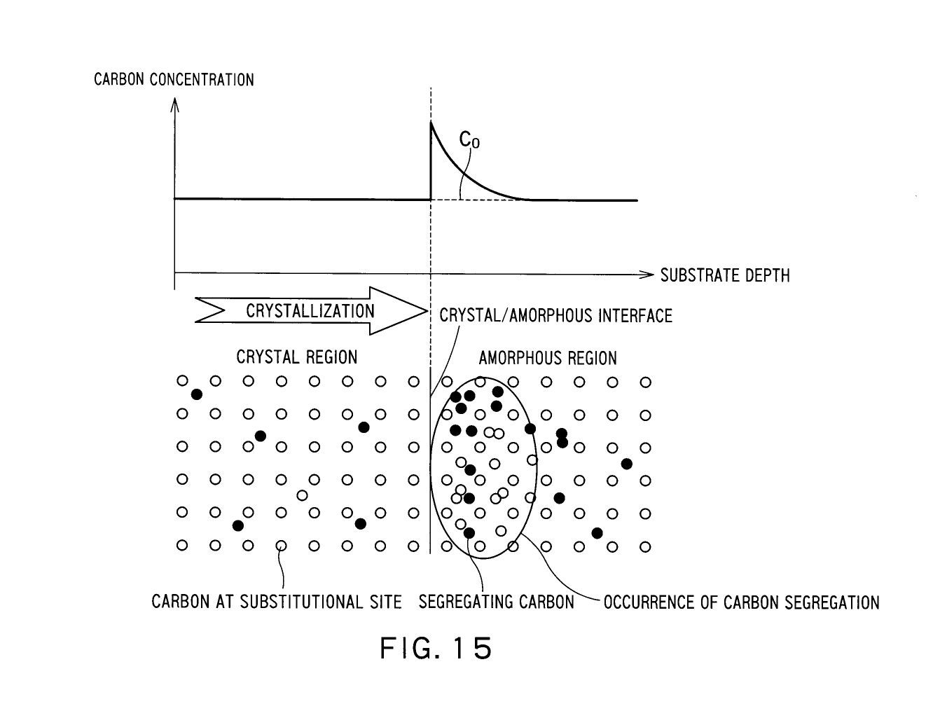

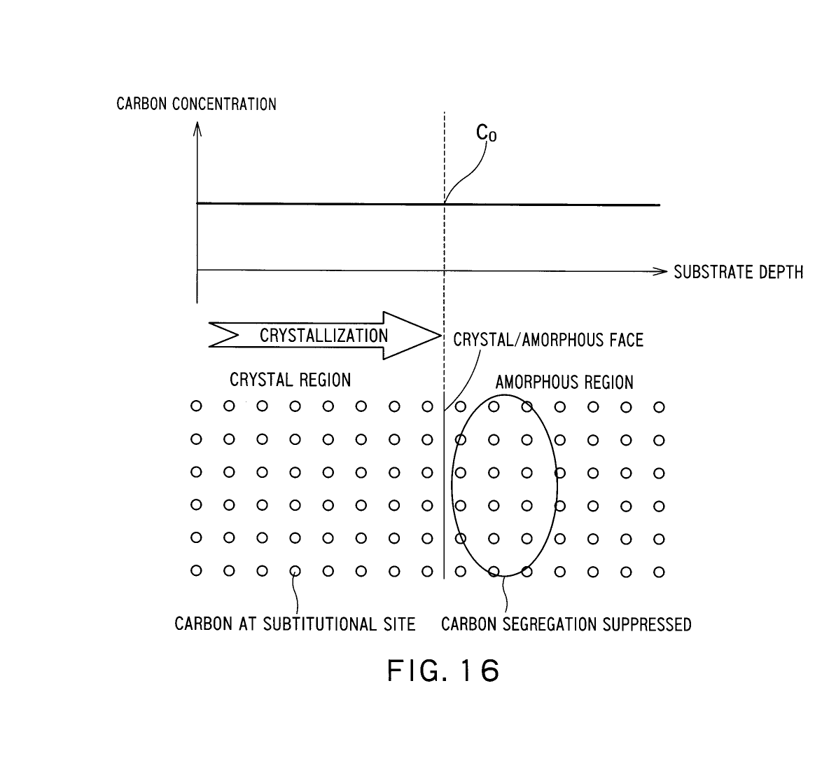

Here, FIG. 15 shows a conventional model in the vicinity of a crystal/amorphous interface of a silicon substrate after heat treatment for activation and the relationship of a carbon concentration with respect to a depth of the substrate. FIG. 16 shows a model of the third embodiment in the vicinity of a crystal/amorphous interface of a silicon substrate after heat treatment for activation and the relationship of a carbon concentration with respect to a depth of the substrate.

In the conventional model, the concentration of carbon supplied to an impurity-implanted layer is higher than the maximum value (solubility limit) CO of the concentration of carbon that is substituted at substitutional sites of a silicon crystal by heat treatment for activation. Therefore, as shown in FIG. 15, surplus carbon that is not substituted by activation segregates from the crystal region to the amorphous region.

On the other hand, in the model of this third embodiment, conditions of ion implantation of one of the carbon cluster ion, the carbon monomer ion and the molecular ion containing carbon are set so that the peak value of the carbon concentration in the impurity-implanted layer before heat treatment for activation is equal to or less than the maximum value (solubility limit) CO of the carbon concentration at substitutional sites of silicon in the impurity-implanted layer after the heat treatment.

This setting of conditions of ion implantation allows the concentration of carbon supplied to the impurity-implanted layer to be lower than the concentration of carbon substituted at substitutional sites of a silicon crystal by heat treatment for activation.

Thus, as shown in FIG. 16, by the heat treatment, ion-implanted carbon is sufficiently substituted at substitutional sites of a silicon crystal. Therefore, carbon segregation is suppressed in the vicinity of the crystal/amorphous interface.

Accordingly, surplus carbon that is not substituted by activation is prevented from segregating in the amorphous region. That is, crystal defects as described above can be suppressed.

Note that conditions of ion implantation are similarly set in the case of ion implanting of carbon monomer ions and molecular ions containing carbon described above.

As described above, with a method of manufacturing a semiconductor device according to the present embodiment, an n-type FET with an improved operation speed can be formed while crystal defects and the like in the impurity-implanted layer are suppressed.

What is claimed is:

1. A method of manufacturing a semiconductor device for forming an n-type FET, comprising:
forming an isolation insulating film on a surface of the semiconductor substrate consisting primarily of silicon, the isolation insulating film partitioning a device region of the semiconductor substrate;
forming a gate insulating film on the device region of the semiconductor substrate;
forming a gate electrode on the gate insulating film;
amorphizing regions to be source/drain contact regions adjacent to the gate electrode, of the device region, by first ion implanting one of a carbon cluster ion, a carbon monomer ion and a molecular ion containing carbon into the regions to be the source/drain contact regions;
forming an impurity-implanted layer to be the source/drain contact regions by second ion implanting at least one of arsenic and phosphorus as an n-type impurity into the amorphized regions; and
activating the carbon and the impurity in the impurity-implanted layer by heat treatment.

2. A method of manufacturing a semiconductor device for forming an n-type FET, comprising:
forming an isolation insulating film on a surface of the semiconductor substrate consisting primarily of silicon, the isolation insulating film partitioning a device region of the semiconductor substrate;
forming a gate insulating film on the device region of the semiconductor substrate;
forming a gate electrode on the gate insulating film;
amorphizing regions to be source/drain contact regions adjacent to the gate electrode, of the device region, by first ion implanting at least one of arsenic and phosphorus as an n-type impurity into the regions to be the source/drain contact regions;
forming an impurity-implanted layer to be the source/drain contact regions by second ion implanting one of a carbon cluster ion, a carbon monomer ion and a molecular ion containing carbon into the amorphized regions; and
activating the carbon and the impurity in the impurity-implanted layer by heat treatment.

3. The method of manufacturing a semiconductor device according to claim 1, wherein the carbon cluster ion is at least one of C₇H₇ and C₅H₅.

4. The method of manufacturing a semiconductor device according to claim 2, wherein the carbon cluster ion is at least one of C₇H₇ and C₅H₅.

5. The method of manufacturing a semiconductor device according to claim 1, wherein, in the impurity-implanted layer, a concentration of the impurity is maximum near a depth at which a carbon concentration is maximum.

6. The method of manufacturing a semiconductor device according to claim 2, wherein, in the impurity-implanted layer, a concentration of the impurity is maximum near a depth at which a carbon concentration is maximum.

7. The method of manufacturing a semiconductor device according to claim 1, further comprising:
activating the carbon and the impurity in the impurity-implanted layer by RTA after forming the impurity-implanted layer; and
activating thereafter the carbon and the impurity in the impurity-implanted layer by the heat treatment.

8. The method of manufacturing a semiconductor device according to claim 2, further comprising:
activating the carbon and the impurity in the impurity-implanted layer by RTA after forming the impurity-implanted layer; and
activating thereafter the carbon and the impurity in the impurity-implanted layer by the heat treatment.

9. The method of manufacturing a semiconductor device according to claim 1, wherein a peak value of the carbon concentration in the impurity-implanted layer before the heat treatment is equal to or less than the carbon concentration at a substitution site of silicon in the impurity-implanted layer after the heat treatment by setting a condition for the first ion implanting of one of the carbon cluster ion, the carbon monomer ion and the molecular ion containing carbon.

10. The method of manufacturing a semiconductor device according to claim 2, wherein a peak value of the carbon concentration in the impurity-implanted layer before the heat treatment is equal to or less than the carbon concentration at a substitution site of silicon in the impurity-implanted layer after the heat treatment by setting a condition for the second ion implanting of one of the carbon cluster ion, the carbon monomer ion and the molecular ion containing carbon.

11. The method of manufacturing a semiconductor device according to claim 1, wherein treatment time of the heat treatment is in a range from 0.2 to 2.0 ms.

12. The method of manufacturing a semiconductor device according to claim 2, wherein treatment time of the heat treatment is in a range from 0.2 to 2.0 ms.

13. The method of manufacturing a semiconductor device according to claim 1, wherein a substrate surface temperature is in a range from 1200 to 1400° C. in the heat treatment.

14. The method of manufacturing a semiconductor device according to claim 2, wherein a substrate surface temperature is in a range from 1200 to 1400° C. in the heat treatment.

15. The method of manufacturing a semiconductor device according to claim 1, wherein the heat treatment is one of Xe flash lamp annealing and laser annealing.

16. The method of manufacturing a semiconductor device according to claim 2, wherein the heat treatment is one of Xe flash lamp annealing and laser annealing.

17. The method of manufacturing a semiconductor device according to claim 1, wherein the device region is a p-type well diffusion layer region formed on a surface of the semiconductor substrate.

18. The method of manufacturing a semiconductor device according to claim 2, wherein the device region is a p-type well diffusion layer region formed on a surface of the semiconductor substrate.

19. The method of manufacturing a semiconductor device according to claim 1, further comprising:
activating the carbon and the impurity in the impurity-implanted layer by RTA after the second ion implanting the impurity; and
activating thereafter the carbon and the impurity in the impurity-implanted layer by the heat treatment.

20. The method of manufacturing a semiconductor device according to claim 2, further comprising:
activating the carbon and the impurity in the impurity-implanted layer by RTA after the second ion implanting one of the carbon cluster ion, the carbon monomer ion and the molecular ion containing carbon; and
activating thereafter the carbon and the impurity in the impurity-implanted layer by the heat treatment.
